(19) United States
(12) Patent Application Publication
(10) Pub. No.: US 2023/0405972 A1
(43) Pub. Date: Dec. 21, 2023

(54) ELASTIC MEMBER AND DISPLAY DEVICE COMPRISING SAME

(71) Applicant: LG INNOTEK CO., LTD., Seoul (KR)

(72) Inventors: Sang Jun KO, Seoul (KR); Sung Won KANG, Seoul (KR); Jung Min GWAK, Seoul (KR)

(21) Appl. No.: 18/037,692

(22) PCT Filed: Dec. 22, 2021
(86) PCT No.: PCT/KR2021/019553

§ 371 Date: May 18, 2023

(30) Foreign Application Priority Data
Jan. 4, 2021 (KR) 10-2021-0000433

(51) Int. Cl. B32B 15/08; B32B 3/30; B32B 3/26; B32B 15/20; B32B 7/12

(52) U.S. Cl. CPC B32B 15/08; B32B 3/30; B32B 3/266; B32B 15/20; B32B 7/12; B32B 2307/51; B32B 2307/7376; B32B 2307/302; B32B 2307/54; B32B 2457/208

(57) ABSTRACT

An elastic member according to an embodiment comprises: a first area; and a second area, the first area being defined as a folding area and the second area being defined as an unfolding area, wherein the elastic member comprises a first layer, a second layer on the first layer, and a third layer between the first layer and the second layer, the first layer comprises a metal, the second layer comprises a metal or plastic, the first layer comprises a plurality of pattern portions having a hole or groove shape, the third layer has a storage modulus of 29-150 kPa, and the third layer contacts the first layer with a first adhesive strength and contacts the second layer with a second adhesive strength, and the first adhesive strength and the second adhesive strength are 400-1800 gf/in.

### TECHNICAL FIELD

Embodiments relate to an elastic member and a display device including the same.

### BACKGROUND ART

Recently, there is an increasing demand for a flexible or foldable display device capable of easily carrying various applications and displaying an image on a large screen when being carried.

Such a flexible or foldable display device is folded or partially bent when being carried or stored, and may be implemented with the display unfolded when displaying images. Accordingly, an image display region may be increased, and a user may easily carry the display.

After the flexible or foldable display device is folded or bent, a restoration process of unfolding the flexible display device again may be repeated.

That is, since the flexible or foldable display device repeats folding and unfolding operations, a substrate of the flexible display device is required to have a certain strength and elasticity, and cracks and deformations should not occur in the substrate during folding and restoring.

Meanwhile, a display substrate that is an elastic member constituting the flexible or foldable display device may be applied to the display device. That is, the display substrate may be applied to the display device in which a screen is displayed by disposing a display panel or a touch panel on the elastic member.

In order to implement the flexible or foldable display device, a plurality of pattern holes or grooves capable of dispersing tensile stress and compressive stress may be formed in the elastic member.

In addition, an impact-absorbing layer for absorbing an impact applied to the elastic member and a planarizing layer for planarizing the pattern holes or the grooves of the elastic member may be disposed on the elastic member.

Accordingly, there is a problem that the number of processes for manufacturing the display device including the elastic member increases, and the overall thickness of the display device is increased, so that a curvature size of the display device is limited.

Therefore, there is a need for an elastic member having a new structure capable of solving the above problems.

### DISCLOSURE

### Technical Problem

An embodiment is directed to providing an elastic member capable of implementing a thin thickness and having improved foldable characteristics and a display device including the same.

### Technical Solution

An elastic member according to an embodiment includes: a first region defined as a folding region and a second region defined as an unfolding region; and a first layer, a second layer on the first layer, and a third layer between the first layer and the second layer, wherein the first layer includes a metal, the second layer includes metal or plastic, the first layer includes a plurality of pattern portions having a hole or groove shape, the third layer has a storage modulus of 29 kPa to 150 kPa, the third layer adheres to the first layer with a first adhesive force and adheres to the second layer with a second adhesive force, and the first adhesive force and the second adhesive force are 400 gf/in to 1800 gf/in.

### Advantageous Effects

An elastic member according to an embodiment can absorb an impact applied to the elastic member while the third layer of the elastic member adheres to the first layer and the second layer.

Accordingly, since there is no need to dispose a separate impact-absorbing layer on the elastic member, a stacked structure of the elastic member can be simplified.

Accordingly, process efficiency of the elastic member can be improved, and since a thickness of the elastic member may be reduced, folding properties of the elastic member can be improved.

In addition, in the elastic member according to the embodiment, the second layer for a surface flatness of the elastic member according to a pattern portion formed on the first layer may include metal or plastic.

Accordingly, when it is desired to further implement the folding properties in the elastic member, the plastic can be applied as the second layer, and when it is desired to further implement strength properties in the elastic member, the metal can be applied as the second layer.

Accordingly, by changing the material and thickness of the second layer according to an application of the elastic member, the properties of the elastic member can be implemented according to the application.

### DESCRIPTION OF DRAWINGS

FIG. 1 is a perspective view of a display device according to an embodiment.

FIG. 2 is a perspective view of an elastic member according to an embodiment.

FIG. 3 is a side view of the elastic member according to the embodiment before folding.

FIG. 4 is a side view of the elastic member according to the embodiment after folding.

FIGS. 5 to 7 are cross-sectional views for describing a layer structure of the elastic member according to the embodiment.

FIG. 8 is a top view of a first surface of a second layer of the elastic member according to the embodiment.

FIG. 9 is a top view of a second surface of the second layer of the elastic member according to the embodiment.

FIG. 10 is another top view of the first surface of the second layer of the elastic member according to the embodiment.

FIGS. 11 and 12 are cross-sectional views for describing an arrangement structure of the elastic member according to the embodiment.

FIGS. 13 to 14 are cross-sectional views of a flexible support including the elastic member according to the embodiment.

FIGS. 15 and 16 are cross-sectional views of a display device including the flexible support according to the embodiment.

FIG. 17 is a view for describing an example in which the display device according to the embodiment is applied.

### Modes of the Invention

Hereinafter, embodiments of the present disclosure will be described in detail with reference to the accompanying drawings. However, the spirit and scope of the present disclosure is not limited to a part of the embodiments described, and may be implemented in various other forms, and within the spirit and scope of the present disclosure, one or more of the elements of the embodiments may be selectively combined and replaced. In addition, unless expressly otherwise defined and described, the terms used in the embodiments of the present disclosure (including technical and scientific terms) may be construed the same meaning as commonly understood by one of ordinary skill in the art to which the present disclosure belongs, and the terms such as those defined in commonly used dictionaries may be interpreted as having a meaning that is consistent with their meaning in the context of the relevant art.

In addition, the terms used in the embodiments of the present disclosure are for describing the embodiments and are not intended to limit the present disclosure. In this specification, the singular forms may also include the plural forms unless specifically stated in the phrase, and may include at least one of all combinations that may be combined in A, B, and C when described in “at least one (or more) of A (and), B, and C”.

Further, in describing the elements of the embodiments of the present disclosure, the terms such as first, second, A, B, (a), and (b) may be used. These terms are only used to distinguish the elements from other elements, and the terms are not limited to the essence, order, or order of the elements.

In addition, when an element is described as being “connected”, “coupled”, or “connected” to another element, it may include not only when the element is directly “connected” to, “coupled” to, or “connected” to other elements, but also when the element is “connected”, “coupled”, or “connected” by another element between the element and other elements.

Further, when described as being formed or disposed “on (over)” or “under (below)” of each element, the “on (over)” or “under (below)” may include not only when two elements are directly connected to each other, but also when one or more other elements are formed or disposed between two elements.

Furthermore, when expressed as “on (over)” or “under (below)”, it may include not only the upper direction but also the lower direction based on one element.

Hereinafter, an elastic member according to an embodiment and a folding support and a display device including the same will be described with reference to the drawings.

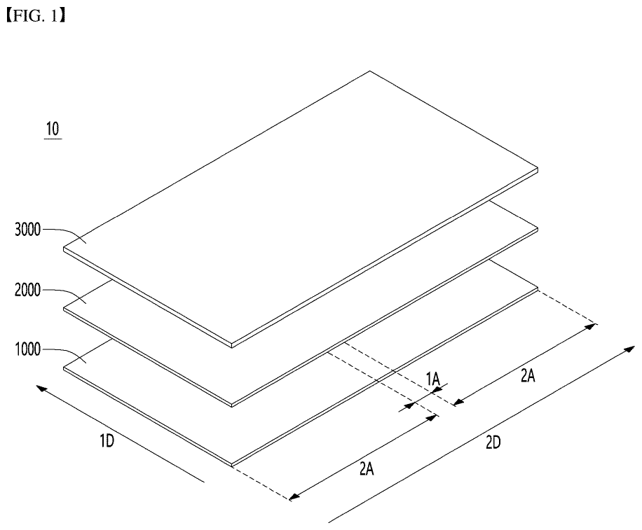

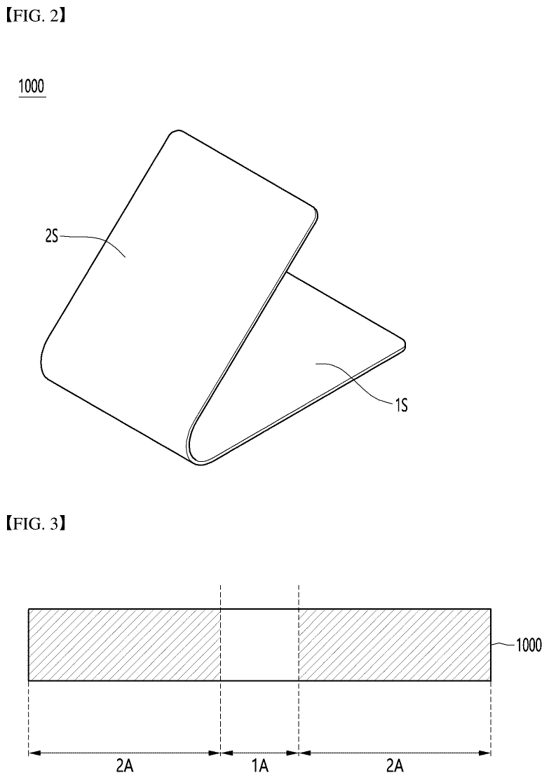

FIG. 1 is a perspective view of a display device according to an embodiment, and FIGS. 2 to 4 are perspective views and cross-sectional views of an elastic member of the display device according to the embodiment.

Referring to FIG. 1, a display device 10 according to an embodiment may include an elastic member 1000 and a panel including a display panel 2000 and a touch panel 3000 disposed on the elastic member 1000.

The elastic member 1000 may support the display panel 2000 and the touch panel 3000. That is, the elastic member 1000 may be a support substrate supporting the display panel 2000 and the touch panel 3000.

Meanwhile, the touch panel 3000 may be integrally formed with the display panel 2000. For example, the touch panel 3000 may be integrally formed with the display panel 2000 in an on-cell or in-cell method.

The elastic member 1000 may include a metallic material and a non-metallic material. In detail, the elastic member 1000 may be formed of a plurality of layers, and the plurality of layers may include at least one of the metallic material and the non-metallic material. For example, the elastic member 1000 may include metal, metal alloy, plastic, a composite material (e.g., carbon fiber reinforced plastic, a magnetic or conductive material, a glass fiber reinforced material, etc.), ceramic, sapphire, glass, and the like.

The elastic member 1000 may be flexible or foldable. That is, the elastic member 1000 may be folded or bent in one direction. That is, the elastic member 1000 may be a substrate for display applied to a flexible display device or a foldable display device.

In the elastic member 1000, a first direction 1D and a second direction 2D that is different from the first direction 1D may be defined. For example, the first direction 1D may be defined as the same direction as a folding axis direction of the elastic member 1000, and the second direction may be a direction perpendicular to the first direction.

One direction of the first direction 1D and the second direction 2D may be defined as a width direction of the elastic member 1000, and the other direction may be defined as a length direction of the elastic member 1000.

The elastic member 1000 may be folded with any one of the width direction and the length direction of the elastic member 1000 as a folding axis.

Hereinafter, for convenience of description, the first direction is defined as the same direction as the folding axis. In addition, the first direction is defined as the width direction of the elastic member 1000, and the second direction is defined as the length direction of the elastic member 1000.

The elastic member 1000 may include at least two regions. In detail, the elastic member 1000 may include a first region 1A and a second region 2A.

The first region 1A may be defined as a region where the elastic member 1000 is folded. That is, the first region 1A may be defined as a region where the elastic member 1000 and the display device 10 including the elastic member 1000 are folded. That is, the first region 1A may be a folding region.

In addition, the second region 2A may be defined as a region where the elastic member 1000 is not folded. That is, the second region 2A may be defined as a region where the elastic member 1000 and the display device 10 including the elastic member 1000 are not folded. That is, the second region 2A may be an unfolding region.

The first region 1A and the second region 2A will be described in detail below.

The display panel 2000 may be disposed on the elastic member 1000.

The display panel 2000 may include a plurality of pixels including a switching thin film transistor, a driving thin film transistor, a power storage device, and an organic light-emitting diode (OLED).

The display panel may include a substrate, a gate line disposed on the substrate, a data line isolated from the gate line, and a common power line. In general, one pixel may be defined by the gate line, the data line, and the common power line as a boundary.

The substrate may include a material having flexible properties such as a plastic film, and the display panel 2000 may be implemented by disposing an organic light-emitting diode and a pixel circuit on a flexible film.

The touch panel 3000 may be disposed above the display panel 2000. The touch panel 3000 may implement a touch function in the foldable display device or the flexible display device, and the touch panel may be omitted in a foldable display device or a flexible display device that simply displays an image without the touch function.

The touch panel 3000 may include a substrate and a touch electrode disposed on the substrate.

The substrate of the touch panel 3000 may include a material having flexible properties such as a plastic film, and the touch panel 3000 may be implemented by disposing the touch electrode on the flexible film.

When the touch panel 3000 is integrally formed with the display panel 2000, the substrate of the touch panel 3000 may be a substrate of the display panel or a part of the display panel.

Meanwhile, the elastic member 1000 and the display panel 2000 may have different sizes.

For example, an area of the elastic member 1000 may be 90% or more to 110% or less of an area of the display panel 2000. In detail, the area of the elastic member 1000 may be 95% or more to 105% or less of the area of the display panel 2000. In more detail, the area of the elastic member 1000 may be 97% or more to 100% or less of the area of the display panel 2000.

When the area of the elastic member 1000 is 90% or less of the area of the display panel 2000, support force of the elastic member 1000 supporting the display panel 2000 or the touch panel 3000 decreases, and thus, a curl phenomenon or the like may occur in the unfolding region of the elastic member 1000. Accordingly, when a user visually recognizes a screen region, visibility may be deteriorated, and when a touch is driven, a screen of a touch region may be incomplete due to a curled region, and thus a touch malfunction may occur.

In addition, when the area of the elastic member 1000 increases to be 110% or more of the area of the display panel 2000, the support force for supporting the display panel or the touch panel may be secured by the elastic member 1000, but a bezel region of a display device including the substrate, the display panel, and the touch panel may increase. Accordingly, it is impossible to provide a wide effective screen region to the user, which may cause inconvenience in using the display device.

Meanwhile, although not shown in the drawings, a cover window protecting the foldable display device or the flexible display device may be additionally disposed above the touch panel 3000 or above the display panel 2000 (when the touch panel is omitted).

Meanwhile, the elastic member 1000, the display panel 2000, and the touch panel 3000 may be adhered to each other through an adhesive layer or the like.

Referring to FIG. 2, the elastic member 1000 may be bent in one direction.

In detail, the elastic member 1000 may include a first surface 1S and a second surface 2S opposite to the first surface 1S. In the elastic member 1000, the first surface 1S or the second surface 2S may be bent to face each other.

However, the embodiment is not limited thereto, and the second surface and the first surface of the elastic member 1000 may be bent to alternately face each other. That is, the elastic member 1000 may include a plurality of first regions and a plurality of second regions.

In the following description, as shown in FIG. 2, it will be mainly described that the elastic member 1000 is bent in a direction in which the first surfaces 1S face each other.

The first region 1A and the second region 2A may be regions defined when the elastic member 1000 is bent in the direction in which the first surfaces 1S face each other.

In detail, the elastic member 1000 is bent in one direction, and the elastic member 1000 may be divided into the first region 1A which is a folded region (folding region) and the second region 2A which is an unfolded region (unfolding region).

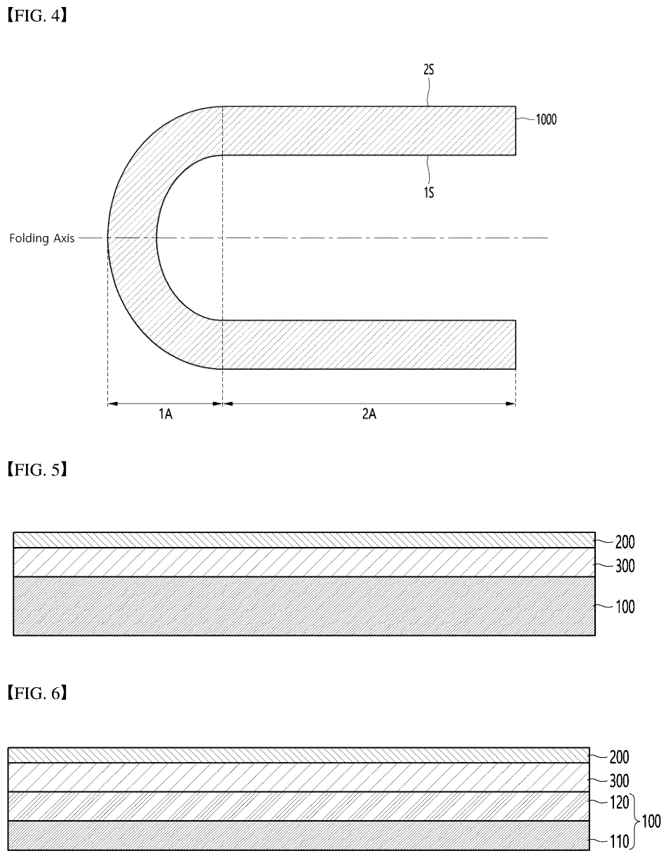

Referring to FIG. 3 and FIG. 4, the elastic member 1000 may include a first region 1A that is a region where the elastic member 1000 is bent. The elastic member 1000 may include a second region 2A that is not bent and is disposed adjacent to the first region 1A.

The first region 1A may be disposed between the second regions 2A.

However, the embodiment is not limited thereto, and the first region 1A may be further formed outside the second region 2A.

The first region 1A and the second region 2A may be formed on the same elastic member 1000. That is, the first region 1A and the second region 2A may be formed integrally with each other without being separated from the same elastic member 1000.

Sizes of the first region 1A and the second region 2A may be different from each other. In detail, the size of the second region 2A may be greater than the size of the first region 1A.

In addition, an area of the first region 1A of the elastic member 1000 may be 1% or more to 30% or less of an entire area of the elastic member 1000. In detail, the area of the first region 1A of the elastic member 1000 may be 5% or more to 20% or less of the entire area of the elastic member 1000. The area of the first region 1A of the elastic member 1000 may be 10% or more to 15% or less of the entire area of the elastic member 1000.

When the area of the first region 1A of the elastic member 1000 is less than 1% of the entire area of the elastic member 1000, cracks may occur at the interface of the folding and unfolding regions of the elastic member 1000 while the folding and restoring of the substrate is repeated, and thus folding reliability of the elastic member 10000 may be deteriorated.

In addition, when the area of the first region 1A of the elastic member 1000 exceeds 30% of the entire area of the elastic member 1000, curl may occur in the folding region of the display panel 2000 when the substrate is folded. Accordingly, when the user visually recognizes the screen region, the visibility may be deteriorated, and when the touch is driven, the screen of the touch region may be incomplete due to the curled region, and thus the touch malfunction may occur.

In the drawings, it is illustrated that the first region 1A is positioned in a central portion of the elastic member 1000, but the embodiment is not limited thereto. That is, the first region 1A may be positioned in one end and an end region of the elastic member 1000. That is, the first region 1A may be positioned at one end and the end region of the elastic member 1000 such that the size of the first region 1A is asymmetric.

FIG. 4 is a side view of the substrate for display after the substrate is folded.

As the elastic member 1000 is folded in one direction, the first region 1A and the second region 2A may be formed on the elastic member 1000. That is, the folding region formed by folding the elastic member 1000 in one direction and the unfolding region positioned at both ends of the folding region may be formed in the elastic member 1000.

The folding region may be defined as a region where a curvature R is formed, and the unfolded region may be defined as a region where the curvature R is not formed or the curvature is close to zero.

Referring to FIGS. 3 and 4, the elastic member 1000 may be folded in one direction to be formed in an order of the unfolding region, the folding region, and the unfolding region.

A plurality of pattern portions may be formed in at least one of the first region 1A and the second region 2A in order to reduce and disperse stress generated when the elastic member 1000 is folded. The pattern portions will be described in detail below.

Hereinafter, the elastic member according to the embodiment will be described in detail with reference to FIGS. 5 to 12.

FIGS. 5 to 7 are cross-sectional views for describing a layer structure of the elastic member 1000.

Referring to FIG. 5, the elastic member 1000 may include a first layer 100, a second layer 200, and a third layer 300. In detail, the elastic member 1000 may include the first layer 100, the second layer 200 on the first layer 100, and the third layer 300 between the first layer 100 and the second layer 200.

In detail, the first layer 100 may include a metal or a metal alloy.

The first layer 100 may include a material having a thermal conductivity of about 20 W/mk or more. In detail, the first layer 100 may have a thermal conductivity of 30 W/mk to 200 W/mk. In more detail, the first layer 100 may have a thermal conductivity of 50 W/mk to 160 W/mk. In more detail, the first layer 100 may have a thermal conductivity of 80 W/mk to 120 W/mk.

When the thermal conductivity of the first layer 100 is less than 20 W/mk, heat of the elastic member may not be effectively dissipated to the outside. In addition, when the thermal conductivity of the first layer 100 exceeds 200 W/mk, a thickness of the first layer 100 may be increased in order to increase the thermal conductivity of the first layer 100, and a heat dissipation effect due to the increase in the thermal conductivity may be small.

In addition, the first layer 100 may have a yield strength of about 0.8 GPa or more. In detail, the yield strength of the first layer 100 may be 0.9 GPa or more. In more detail, the yield strength of the first layer 100 may be 1.0 GPa or more.

When the yield strength of the first layer 100 is less than 0.8 GPa, a strength of the elastic member is reduced when the elastic member is folded, whereby plastic deformation may occur in the elastic member in a process of folding and restoring the elastic member 1000.

In addition, the first layer 100 may be formed to a thickness of 60% or less of the overall thickness of the elastic member 1000. In detail, the first layer 100 may have a thickness of 40% to 60% of the overall thickness of the elastic member 1000. For example, the elastic member 1000 may have a thickness of 150 μm to 300 μm, and the first layer 100 may have a thickness of 40% to 60% of the overall thickness of the elastic member 1000.

When the thickness of the first layer 100 exceeds 60% of the overall thickness of the elastic member 1000, the overall flexible or foldable characteristics of the elastic member 1000 may be reduced due to the increase in the thickness of the first layer 100.

In addition, when the thickness of the first layer 100 is less than 40% of the overall thickness of the elastic member 1000, the yield strength of the first layer 100 is reduced, so that plastic deformation may occur when the elastic member 1000 is folded.

The first layer 100 may include one or a plurality of metals. For example, the first layer 100 may include copper (Cu). Alternatively, the first layer 100 may be formed of an alloy including at least one of nickel (Ni), chromium (Cr), iron (Fe), titanium (Ti), manganese (Mn), molybdenum (Mo), silver (Ag), zinc (Zn), nitrogen (N), and aluminum (Al) together with copper (Cu).

As described above, since the first layer 100 has a thermal conductivity within the above range, the elastic member 1000 may serve as a heat dissipation layer when the elastic member 1000 is applied to the display device, so that it may dissipate heat effectively.

In addition, since the first layer 100 has a yield strength and a thickness within the above range, it is possible to prevent plastic deformation of the elastic member when the elastic member is folded, thereby improving folding properties.

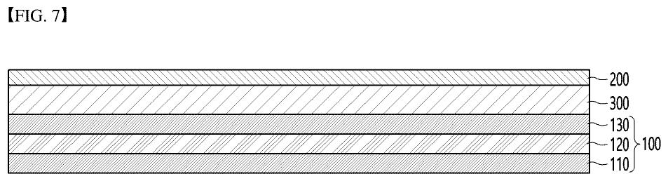

Meanwhile, referring to FIGS. 6 and 7, the first layer 100 may be formed in multiple layers.

Referring to FIG. 6, the first layer 100 may include a 1-1 layer 110 and a 1-2 layer 120 on the 1-1 layer 110.

The 1-1 layer 110 and the 1-2 layer 120 may include a metal material. In detail, the 1-1 layer 110 and the 1-2 layer 120 may include different metal materials.

For example, the 1-1 layer 110 and the 1-2 layer 120 may include materials having different thermal conductivity. In detail, the 1-1 layer 110 may include a material having thermal conductivity higher than that of the 1-2 layer 120.

In addition, the 1-1 layer 110 and the 1-2 layer 120 may include materials having different yield strengths. In detail, the 1-2 layer 120 may include a material having a yield strength higher than that of the 1-1 layer 110.

For example, the 1-1 layer 110 may include copper or a copper alloy, and the 1-2 layer 120 may include SUS, but the embodiment is not limited thereto, and the 1-1 layer 110 and the 1-2 layer 120 may include various materials satisfying the thermal conductivity and the yield strength.

In addition, the 1-1 layer 110 and the 1-2 layer 120 may be disposed in direct contact with each other. In detail, the 1-1 layer 110 and the 1-2 layer 120 may be manufactured in a clad method.

Clad bonding is a method of bonding the 1-1 layer 110 and the 1-2 layer 120 by a method such as welding, rolling, casting, or extrusion without bonding using an adhesive, and it is possible to show better bonding force over time by destroying a mutual organization of each layer and stabilizing the bonding of each layer through interstitial penetration.

For example, the bonding may be formed by inducing atomic diffusion between dissimilar materials at a layer interface of different layers through rolling. Since the clad bonding may process curved surfaces unlike bonding using an adhesive and uses atomic diffusion bonding rather than bonding using the adhesive, it has an advantage of being able to maintain a bonded state for a long time.

The 1-1 layer 110 and the 1-2 layer 120 may be disposed to have the same or different thicknesses. For example, when it is desired to improve heat dissipation characteristics of the elastic member 1000, a thickness of the 1-1 layer 110 may be disposed to be greater than a thickness of the 1-2 layer 120. Alternatively, in order to improve folding properties of the elastic member 1000, the thickness of the 1-2 layer 120 may be greater than the thickness of the 1-1 layer 110.

That is, the thickness of the 1-1 layer 110 and the thickness of the 1-2 layer 120 may vary according to characteristics to be implemented in the elastic member 1000.

Referring to FIG. 7, the first layer 100 may include a 1-1 layer 110, a 1-2 layer 120 on the 1-1 layer 110, and a 1-3 layer 130 on the 1-2 layer 120.

The 1-1 layer 110, the 1-2 layer 120, and the 1-3 layer 130 may include a metal material. In detail, the 1-1 layer 110, the 1-2 layer 120, and the 1-3 layer 130 may include the same or different metal materials.

For example, the 1-1 layer 110 and the 1-3 layer 130 may include the same material from each other, and the 1-2 layer 120 may include a material different from those of the 1-1 layer 110 and the 1-3 layer 130.

The 1-1 layer 110, the 1-3 layer 130, and the 1-2 layer 120 may include materials having different thermal conductivity. In detail, the 1-1 layer 110 and the 1-3 layer 130 may include a material having thermal conductivity higher than that of the first 1-2 layer 120.

In addition, the 1-1 layer 110, the 1-3 layer 130, and the 1-2 layer 120 may include materials having different yield strengths. In detail, the first 1-2 layer 120 may include a material having a yield strength higher than those of the 1-1 layer 110 and the 1-3 layer 130.

For example, the 1-1 layer 110 and the 1-3 layer 130 may include copper or a copper alloy, and the first 1-2 layer 120 may include SUS, but the embodiment is not limited thereto, and the 1-1 layer 110, the 1-2 layer 120, and the 1-3 layer 130 may include various materials satisfying the thermal conductivity and the yield strength.

In addition, the 1-1 layer 110, the 1-2 layer 120, and the 1-3 layer 130 may be disposed in direct contact with each other. In detail, the 1-1 layer 110, the 1-2 layer 120, and the 1-3 layer 130 may be manufactured by the clad method described above.

The 1-1 layer 110, the 1-2 layer 120, and the 1-3 layer 130 may be disposed to have the same or different thicknesses from each other. For example, when it is desired to improve the heat dissipation characteristics of the elastic member 1000, the thickness of the 1-1 layer 110 and the thickness of the 1-3 layer 130 may be disposed to be greater than the thickness of the 1-2 layer 120. Alternatively, when it is desired to improve the folding properties of the elastic member 1000, the thickness of the 1-2 layer 120 may be disposed to be greater than those of the 1-1 layer 110 and the 1-3 layer 130.

That is, the thickness of the 1-1 layer 110, the thickness of the first 1-2 layer 120, and the thickness of the 1-3 layer 130 may vary depending on the properties to be implemented in the elastic member 1000.

Consequently, the first layer of the elastic member may include at least one of the 1-1 layer, the 1-2 layer, and the 1-3 layer.

Meanwhile, a plurality of pattern portions may be formed in the first layer 100 in order to reduce and disperse compressive stress and tensile stress generated when the elastic member 1000 is folded and restored.

In detail, a hole or groove-shaped pattern portion penetrating the first layer 100 in whole or in part may be formed in the first layer 100.

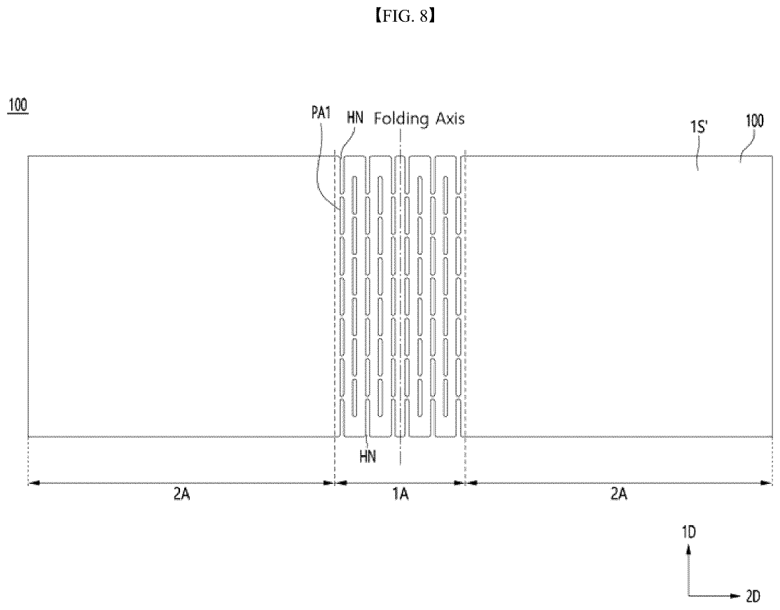

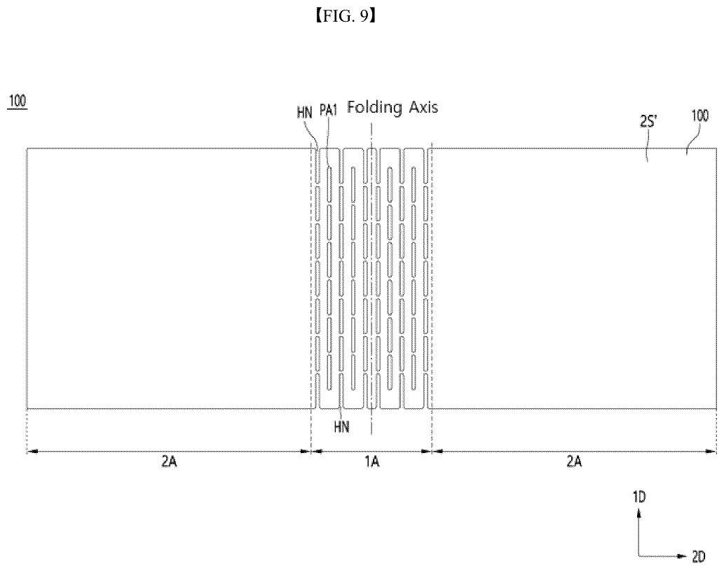

FIGS. 8 and 9 are top views of a first layer 100 of the elastic member 1000. FIG. 8 is a top view of a first′ surface 1S′ of the first layer 100, and FIG. 9 is a top view of a second′ surface 2S′ of the first layer 100.

Referring to FIGS. 8 and 9, the first layer 100 may include a plurality of pattern portions PA. In detail, the first layer 100 may include a first pattern portion PA1 disposed in the first region 1A.

The first pattern portion PA1 may be formed in a hole or groove shape.

In detail, the first pattern portion PA may be formed in a hole shape penetrating the first′ surface 1S′ and the second′ surface 2S′ of the first layer or may be formed in a groove shape formed on the first′ surface 1S′ or the second′ surface 2S′.

The first pattern portion PA1 disposed in the first region 1A, which is a region where the first layer 100 is folded, may easily fold the elastic member 1000 when the first layer 100 is folded. In detail, since the thickness of the first layer 100 is reduced in the region where the elastic member 1000 is folded by the first pattern portion PA1, whereby the compressive stress is reduced, the elastic member 1000 may be easily folded.

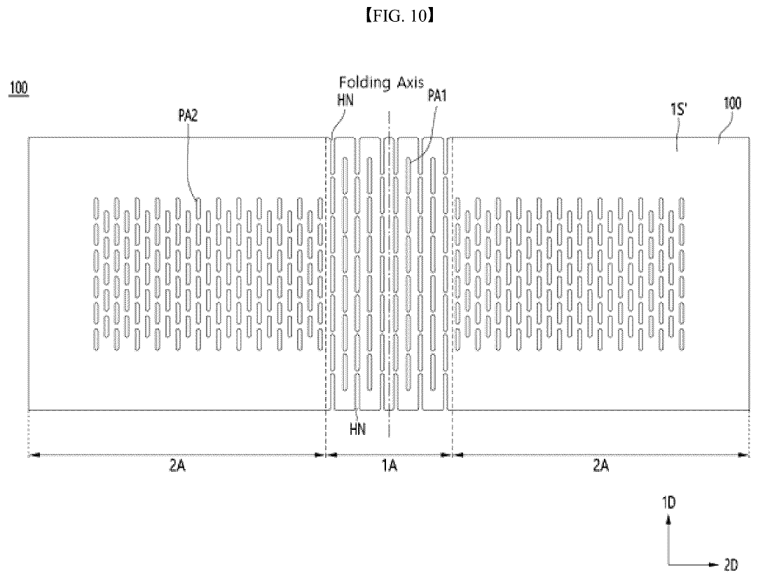

In addition, referring to FIG. 10, the first layer 10 may further include a second pattern portion PA2. In detail, the first layer 100 may further include a second pattern portion PA2 disposed in the second region 2A.

The second pattern portion PA2 may be formed in a hole or groove shape.

In detail, the second pattern portion PA may be formed in a hole shape penetrating the first surface 1S and the second surface 2S of the first layer or may be formed in a groove shape formed on the first surface 1S or the second surface 2S.

The second pattern portion PA2 disposed in the second region 2A, which is a region where the first layer 100 is not folded, may similarly maintain physical characteristics of the first region 1A and the second region 2A.

In detail, a difference in deformation caused by heat in the first region 1A where the first pattern portion PA1 is disposed may be alleviated by the second pattern portion PA2. That is, when heat is applied to the first layer 100, a difference in deformation by heat in the first region 1A and the second region 2A may be alleviated by forming pattern portions in both the first region 1A and the second region 2A. Accordingly, it is possible to prevent the elastic member 1000 from being bent or warped by the first layer 100.

In addition, unevenness of the stress between the first region 1A and the second region 2A may be alleviated by the second pattern portion PA2 formed in the second region 2A to prevent bending of the elastic member.

In addition, when the first layer 100 and the third layer 300 are disposed by the second pattern portion PA2 formed in the second region 2A, since a contact area of the third layer 300 in the first region 1A and the second region 2A may be made uniform, it is possible to prevent adhesion failure of the third layer 300 due to a step difference in the formation of the pattern portion.

The second pattern portion PA2 may be formed in a shape the same as or similar to that of the first pattern portion PA1. In detail, the second pattern portion PA2 may be formed in a shape having a longitudinal direction and a lateral direction, and a longitudinal direction of the second pattern portion PA1 and a longitudinal direction of the first pattern portion PA1 may extend the same or similar directions to each other, and a lateral direction of the second pattern portion PA2 and a lateral direction of the first pattern portion PA1 may extend in the same or similar directions to each other.

Meanwhile, the first layer 100 may include a hinge portion HN. In detail, a plurality of hinge portions HN may be disposed in the first region 1A of the first layer 100. The hinge portion HN is a region where an end region of the first layer 100 is opened for folding of the first layer 100 and may be formed only in the first region 1A. Accordingly, the hinge portion HN is a point at which folding of the elastic member 1000 is started, and the first region 1A and the second region 2A of the elastic member 1000 may be distinguished depending on whether the hinge portion is formed or not.

Referring again to FIGS. 5 to 7, the elastic member 1000 may include the second layer 200. The second layer 200 may be disposed on the first layer 100.

The second layer 200 may be disposed on the first layer 100 to serve to planarize a surface of the first layer 100. As described above, the plurality of pattern portions in the shape of holes or grooves are formed in the first layer 100, and the surface of the first layer 100 may not be flat due to the pattern portions. Accordingly, when a panel or the like is directly adhered to the first layer 100, adhesive force with the panel may be reduced due to surface characteristics of the first layer 100.

Accordingly, the elastic member 1000 may dispose the second layer 200 on the first layer 100 to flatten an adhesive surface on which the elastic member 1000 is adhered to the panel. That is, the second layer 200 may be defined as a planarization layer of the elastic member 1000.

The second layer 200 may include a metal or a non-metal. In detail, the second layer 200 may include metal or plastic. The second layer 200 may include different materials according to characteristics to be implemented among the folding properties and the strength among the characteristics of the elastic member 1000

For example, the second layer 200 may include plastic. For example, the second layer 200 may include polyimide (PI), but the embodiment is not limited thereto.

As the second layer 200 includes plastic, the folding properties of the elastic member 1000 may be further improved. In detail, since the elastic member 1000 includes the second layer 200 including a plastic material having better folding properties than metal, when the elastic member 1000 is folded, the elastic member 1000 may be folded with a smaller radius of curvature, and it is possible to minimize the occurrence of plastic deformation in the second layer 200 in the process of folding and restoring the elastic member 1000.

A thickness of the second layer 200 may be smaller than the thickness of the first layer 100. In addition, the thickness of the second layer 200 may be smaller than a thickness of the third layer 300 to be described below. That is, the second layer 200 may be formed to have the smallest thickness among the layers of the elastic member 1000.

The second layer 200 may be formed to a thickness of 25% or less of the overall thickness of the elastic member 1000. In detail, the second layer 200 may have a thickness of 15% to 25% of the overall thickness of the elastic member 1000. For example, the elastic member 1000 may have a thickness of 150 μm to 300 μm, and the second layer 200 may have a thickness of 15% to 25% of the overall thickness of the elastic member 1000.

That is, when the second layer 200 includes plastic, the elastic member 1000 has a thickness of 150 μm to 300 μm, and the second layer 200 may have a thickness of 15% to 25% of the overall thickness of the elastic member 1000.

When the thickness of the second layer 200 exceeds 25% of the overall thickness of the elastic member 1000, the flexible or foldable characteristics of the elastic member 1000 may be reduced due to the increase in the thickness of the second layer 200.

In addition, when the thickness of the second layer 200 is less than 15% of the overall thickness of the elastic member 1000, since the thickness of the second layer 200 is too small, the process is difficult, and it may be difficult to sufficiently secure a surface flatness of the elastic member 1000 by the second layer 100.

Meanwhile, the second layer 200 may include a metal. As an example, the second layer 200 may include SUS, but the embodiment is not limited thereto.

As the second layer 200 includes a metal, a strength of the elastic member 1000 may be further improved. In detail, since the elastic member 1000 includes the second layer 200 including a metal material having better strength properties than plastic, when the elastic member 1000 is folded, it is possible to prevent the elastic member 1000 from being damaged or broken.

The thickness of the second layer 200 may be smaller than the thickness of the first layer 100. In addition, the thickness of the second layer 200 may be smaller than the thickness of the third layer 300 to be described below. That is, the second layer 200 may be formed to have the smallest thickness among the layers of the elastic member 1000.

In addition, when the second layer 200 includes a metal, the thickness of the second layer 200 may be formed smaller in order to prevent plastic deformation occurring when the elastic member 1000 is folded and restored. That is, when the second layer 200 includes a metal, it may have a smaller thickness than when the second layer 200 includes plastic.

The second layer 200 may be formed to have a thickness of 10% or less of the overall thickness of the elastic member 1000. In detail, the second layer 200 may have a thickness of 4% to 10% of the overall thickness of the elastic member 1000. For example, the elastic member 1000 may have a thickness of 150 μm to 300 μm, and the second layer 200 may have a thickness of 4% to 10% of the overall thickness of the elastic member 1000.

That is, when the second layer 200 includes a metal, the elastic member 1000 may have a thickness of 150 μm to 300 μm, and the second layer 200 may have a thickness of 4% to 10% of the overall thickness of the elastic member 1000.

When the thickness of the second layer 200 exceeds 10% of the overall thickness of the elastic member 1000, plastic deformation may occur in the second layer 200 due to the increase in the thickness of the second layer 200. Therefore, the flexible or foldable characteristics of the elastic member 1000 may be reduced.

In addition, when the thickness of the second layer 200 is less than 4% of the overall thickness of the elastic member 1000, the strength of the elastic member 1000 may be reduced due to a decrease in the thickness of the second layer 200.

The third layer 300 may be disposed between the first layer 100 and the second layer 200. The third layer 300 may be disposed between the first layer 100 and the second layer 200 to adhere the first layer 100 and the second layer 200. That is, the third layer 300 may serve as an adhesive layer in the elastic member 1000.

In detail, the third layer 300 may be adhered to the first layer 100 by a first adhesive force and may be adhered to the second layer 200 by a second adhesive force.

The first adhesive force and the second adhesive force of the third layer 300 may be 400 gf/in or more. In detail, the first adhesive force and the second adhesive force of the third layer 300 may be 400 gf/in to 1800 gf/in.

When the adhesive force of the third layer 300 is less than 400 gf/in, the third layer 300 may be delaminated from the first layer 100 and/or the second layer 200 by compressive stress and tensile stress generated when the elastic member 1000 is folded and restored. In addition, when the adhesive force of the third layer 300 exceeds 1800 gf/in, the first adhesive force and the second adhesive force become too large, and when the elastic member 1000 is folded and restored, compression and tension of the elastic member are limited by the adhesive force, so that damage may occur in the elastic member 1000 in the process of folding and restoring the elastic member 1000.

Since the third layer 300 has an adhesive force within the above range with the first layer 100 and the second layer 200 including metal and non-metal, reliability and folding properties of the elastic member may be improved.

In addition, the third layer 300 may be disposed between the first layer 100 and the second layer 200 to absorb an impact applied to the elastic member 1000. In detail, the third layer 300 may have an elastic force and a recovery rate in order to absorb force according to the impact. That is, the third layer 300 may serve as an impact absorbing layer in the elastic member 1000.

The third layer 300 may have a storage modulus of 29 kPa or more. In detail, the third layer 300 may have a storage modulus of 29 kPa to 150 kPa.

Accordingly, the third layer 300 may have elasticity against deformation and/or force according to an impact applied from the outside. Accordingly, when the impact is applied to the elastic member 1000 from the outside, it is possible to prevent the elastic member 1000 from being damaged or broken by the impact due to the elasticity of the third layer 300.

In addition, creep & recovery of the third layer 300 may be a creep of 250% or less and a recovery of 8% or less. Accordingly, when the impact is applied to the elastic member 1000 from the outside, the third layer 300 has a creep of 250%, so that the recovery is 6% while sufficiently absorbing the impact, and accordingly, it is possible to prevent shape deformation of the elastic member after application of the impact.

In addition, a tangent delta of the third layer 300 may be 0.2 to 1.8 at room temperature (25° C.).

When a force of a certain period is applied to a material, stress is generated in the material, and when deformation occurs according to the stress, an elastic modulus may be determined by stress and deformation.

That is, a phase difference is generated according to a stress (usually sinusoidal stress) that is periodically changed by a time delay due to viscoelastic properties of a material. This causes a phase difference between the applied stress and the expansion, and the elastic modulus dynamically measured in consideration of the phase difference may be explained as a storage modulus and a loss modulus. The storage modulus is a reaction of a material that occurs together with periodic stress as a direct result by a DMA measurement and may correspond to the reversible elasticity of the material. The loss modulus, which is a virtual physical property, is a phase-shifted reaction up to 90° and corresponds to mechanical energy that is converted into heat and irreversibly lost. The phase shift is defined as tans (tangent delta), is a loss factor, and is used to measure damping behavior of the material.

The third layer 300 may have a thickness smaller than the thickness of the first layer 100. In addition, the third layer 300 may have a thickness greater than the thickness of the second layer 200.

The third layer 300 may be formed in a thickness of 35% or less of the overall thickness of the elastic member 1000. In detail, the third layer 300 may have a thickness of 25% to 35% of the overall thickness of the elastic member 1000. For example, the elastic member 1000 may have a thickness of 150 μm to 300 μm, and the third layer 300 may have a thickness of 25% to 35% of the overall thickness of the elastic member 1000.

That is, the elastic member 1000 may have a thickness of 150 μm to 300 μm, and the third layer 300 may have a thickness of 25% to 35% of the overall thickness of the elastic member 1000.

When the thickness of the third layer 300 exceeds 35% of the overall thickness of the elastic member 1000, the flexible or foldable characteristics of the elastic member 1000 may be reduced due to the increase in the thickness of the third layer 300.

In addition, when the thickness of the third layer 300 is less than 25% of the overall thickness of the elastic member 1000, the third layer 300 may be delaminated from the first layer 100 and/or the second layer 200 by compressive stress and tensile stress generated when the elastic member 1000 is folded and restored.

As described above, the third layer 300 may have both adhesive properties and impact absorption properties. That is, the third layer 300 may be an impact-absorbing adhesive layer. In the third layer 300, it is possible to control the adhesive properties and the impact absorption properties of the third layer 300 by controlling a cross linking of a material forming the third layer 300.

Since the third layer 300 has both the adhesive properties and the impact absorption properties, the elastic member may omit a separate impact-absorbing layer. That is, while bonding the first layer and the second layer by the third layer bonding the first layer and the second layer, at the same time, the force or deformation according to the impact applied from the outside may be absorbed by the third layer, and thus the separate impact-absorbing layer is not required.

Accordingly, a process of the elastic member may be facilitated by simplifying a stacking structure of the elastic member. In addition, since the separate impact-absorbing layer and a separate adhesive layer for adhering the impact-absorbing layer may be removed from the elastic member, the overall thickness of the elastic member may be reduced. Accordingly, it is possible to improve the folding properties of the elastic member.

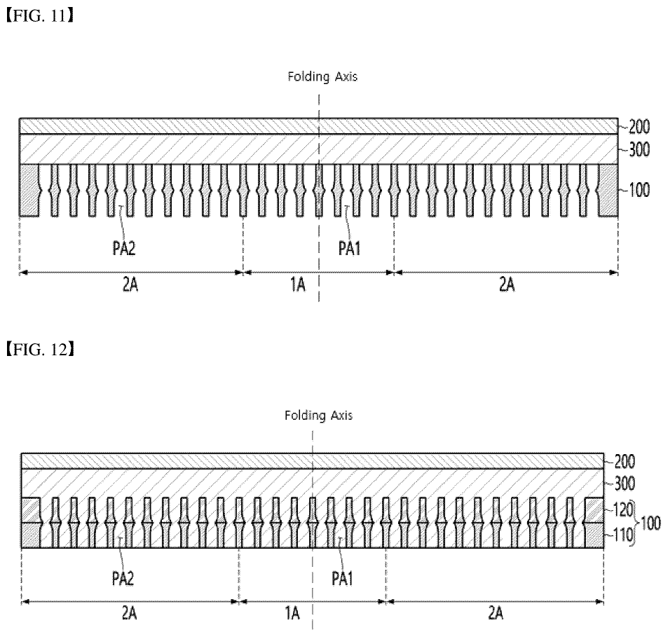

FIGS. 11 and 12 are views for describing arrangement relationship of the third layer 300.

Referring to FIG. 11, the third layer 300 may be disposed on an upper surface of the first layer 100. In detail, after disposing the third layer 300 on the first layer 100 and disposing the second layer 200 on the third layer 300, the first layer 100 and the second layer 200 may be adhered through the third layer 300 by applying pressure on the upper surface.

In this case, the third layer 300 is not disposed inside the first pattern portion PA1 and the second pattern portion PA2 formed on the first layer 100, but the third layer 300 may be disposed only on the upper surface of the first layer 100.

Since the third layer is not disposed inside pattern portions of the first layer, when the elastic member is applied to the display device, refraction and total reflection of light according to the third layer may be minimized, so that light transmittance may be improved.

Alternatively, referring to FIG. 12, the third layer 300 may be disposed on the upper surface of the first layer 100. In detail, the third layer 300 may be disposed inside the first pattern portion PA1 and the second pattern portion PA2 of the first layer 100. In detail, the third layer 300 may be disposed while filling the inside of the first pattern portion PA1 and the second pattern portion PA2 in whole as shown in FIG. 12 or may be disposed while filling the inside of the first pattern portion PA1 and the second pattern portion PA2 in part.

In detail, after disposing the third layer 300 on the first layer 100 and disposing the second layer 200 on the third layer 300, the third layer 300 may adhere the first layer 100 and the second layer 200 while applying pressure onto the second layer 200 and filling both the inside of the first pattern portion PA1 and the second pattern portion PA2 in whole or in part.

Since the third layer is disposed inside the pattern portions of the first layer, when bonding the first layer and the second layer through the third layer, it is possible to improve the adhesive properties by making an area to which the pressure is applied uniform in a first region and a second region of the first layer.

In addition, penetration of impurities through the pattern portions of the first layer may be prevented.

The elastic member according to the embodiment may absorb an impact applied to the elastic member while the third layer of the elastic member adheres to the first layer and the second layer.

Accordingly, since there is no need to dispose a separate impact-absorbing layer on the elastic member, a stacked structure of the elastic member may be simplified.

Accordingly, process efficiency of the elastic member may be improved, and since a thickness of the elastic member may be reduced, the folding properties of the elastic member may be improved.

In addition, in the elastic member according to the embodiment, the second layer for a surface flatness of the elastic member according to the pattern portion formed on the first layer may include metal or plastic.

Accordingly, when it is desired to further implement the folding properties in the elastic member, the plastic may be applied as the second layer, and when it is desired to further implement the strength properties in the elastic member, the metal may be applied as the second layer.

Accordingly, by changing the material and thickness of the second layer according to an application of the elastic member, the properties of the elastic member may be implemented according to the application.

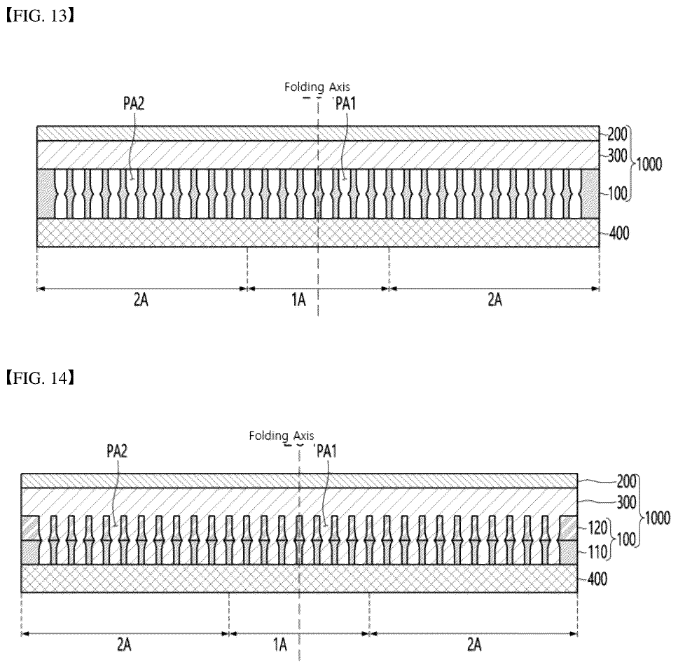

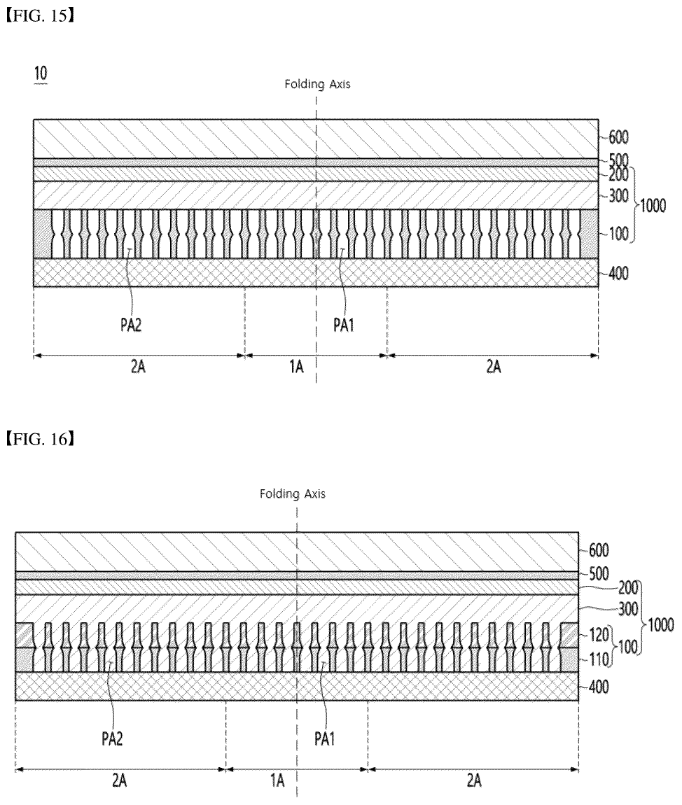

Hereinafter, a folding support including the elastic member according to the embodiment described above will be described with reference to FIGS. 13 and 14.

Referring to FIGS. 13 and 14, the folding support may include the elastic member and a protective layer 400. FIG. 13 is a view showing a folding support in which the third layer is not disposed inside the pattern portion of the first layer, and FIG. 14 is a view showing a folding support in which the third layer formed of a plurality of layers is disposed inside the pattern portion of the first layer.

The folding support may include the above-described elastic member 1000 and the protective layer 400 disposed under the elastic member 10. In detail, the protective layer 400 may be disposed under the first layer 100 or the 1-1 layer 110 of the elastic member 1000.

Although not shown in the drawings, an adhesive layer is disposed between the protective layer 400 and the first layer 100 or between the protective layer 400 and the 1-1 layer 110, and the elastic member 1000 and the protective layer 400 may be adhered through the adhesive layer.

The protective layer 400 may have a color. For example, the protective layer 400 may be formed in a black-based color.

The protective layer 400 may include metal particles. For example, the protective layer 400 may include copper particles. Accordingly, heat generated in the display device may be dissipated through the protective layer 400 by improving a thermal conductivity of the protective layer 400.

The protective layer 400 may be disposed on one region of the elastic member 1000. In detail, the protective layer 400 may be disposed in a region corresponding to the first region 1A of the elastic member 1000. Alternatively, the protective layer 400 may be disposed in a region corresponding to the first region 1A and the second region 2A of the elastic member 1000.

For example, the protective layer 400 may be disposed in a region corresponding to the first region 1A and the second region 2A of the elastic member 1000 and may be disposed in an area smaller than the sum of areas of the first region 1A and the second region 2A. In detail, the protective layer 400 may be disposed in an area of 80% to 90% of the sum of the areas of the first region 1A and the second region 2A of the elastic member.

In addition, a thickness of the protective layer 400 may be smaller than the overall thickness of the elastic member 1000. That is, the thickness of the protective layer 400 may be smaller than the sum of thicknesses of the first layer, the second layer, and the third layer of the elastic member 400.

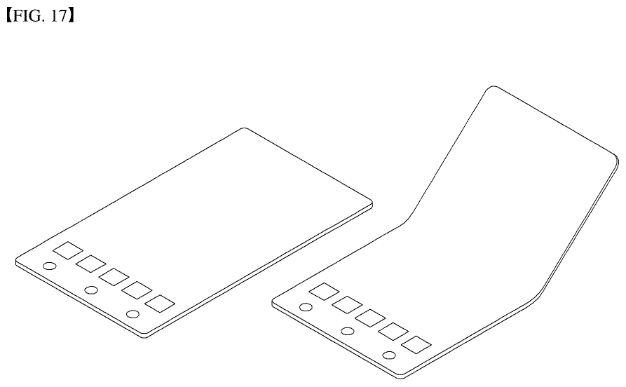

Hereinafter, a display device including the folding support according to the embodiment described above will be described with reference to FIGS. 15 and 16.

Referring to FIGS. 15 and 16, the display device 10 may include the folding support and the panel. FIG. 15 is a view showing a display device in which the third layer of the elastic member is not disposed inside the pattern portion of the first layer, and FIG. 16 is a view showing a display device in which the third layer formed of a plurality of layers is disposed inside the pattern portion of the first layer.

The display device 10 may include the folding support and a panel layer 600 including a touch panel disposed on the folding support and including a display panel and/or the touch panel.

An adhesive layer 500 may be disposed between the elastic member 1000 and the panel layer 600, and the elastic member 1000 may be adhered to the panel layer 600 through the adhesive layer 500.

As described above, since the elastic member 1000 may planarize an adhesive surface of the elastic member by the second layer 200, the elastic member and the panel layer may be stably adhered to each other without being affected by a step difference.

The adhesive layer 500 between the elastic member 1000 and the panel layer 600 may have different properties from the third layer 300 of the elastic member 1000.

In detail, the adhesive layer 500 may have a thickness smaller than that of the third layer 300. For example, the thickness of the adhesive layer 500 may be 5 μm to 15 μm.

In addition, the adhesive layer 500 may have smaller adhesive properties than the third layer 300. In detail, an adhesive force of the adhesive layer 500 may be 400 or less.

In addition, the adhesive layer 500 and the third layer 300 may have different elastic moduli. That is, the adhesive layer 500 does not have an elastic modulus having a storage modulus, creep & recovery and a tangent delta value like the third layer, whereby the adhesive layer 500 may not have elastic properties other than adhesive properties.

The characteristics, structures and effects described in the embodiments above are included in at least one embodiment but are not limited to one embodiment. Furthermore, the characteristic, structure, and effect illustrated in each embodiment may be combined or modified for other embodiments by a person skilled in the art. Thus, it should be construed that contents related to such a combination and such a modification are included in the scope of the present disclosure.

In addition, embodiments are mostly described above, but the embodiments are merely examples and do not limit the present disclosure, and a person skilled in the art may appreciate that several variations and applications not presented above may be made without departing from the essential characteristic of embodiments. For example, each component specifically represented in the embodiments may be varied. In addition, it should be construed that differences related to such a variation and such an application are included in the scope of the present disclosure defined in the following claims.

1. An elastic member comprising:
a first region defined as a folding region and a second region defined as an unfolding region; and
a first layer, a second layer on the first layer, and a third layer between the first layer and the second layer,
wherein the first layer includes a metal,
the second layer includes a metal or plastic,
the first layer includes a plurality of pattern portions having a hole or groove shape,
the third layer has a storage modulus of 29 kPa to 150 kPa,
the third layer adheres to the first layer with a first adhesive force and adheres to the second layer with a second adhesive force, and
the first adhesive force and the second adhesive force are 400 gf/in to 1800 gf/in.

2. The elastic member of claim 1, wherein creep and recovery of the third layer is a creep of 250% or less and a recovery of 8% or less.

3-10. (canceled)

11. The elastic member of claim 1, wherein a thickness of the third layer is smaller than a thickness of the first layer,
wherein the thickness of the third layer is greater than a thickness of the second layer.

12. The elastic member of claim 11, wherein the third layer has a thickness of 25% to 35% of the overall thickness of the elastic member.

13. The elastic member of claim 1, wherein the second layer includes metal or plastic.

14. The elastic member of claim 13, wherein a thickness of the second layer is smaller than the thicknesses of the first layer and the third layer.

15. The elastic member of claim 11, wherein the first layer includes copper or a copper alloy, and
the second layer includes SUS or polyimide.

16. The elastic member of claim 15, wherein the first layer has a thickness of 40% to 60% of the overall thickness of the elastic member, and
the first layer includes at least one of a 1-1 layer, a 1-2 layer, and a 1-3 layer.

17. The elastic member of claim 1, wherein the first layer includes a 1-1 layer and a 1-2 layer on the 1-1 layer,
wherein a thermal conductivity of the 1-1 layer is greater than that of the 1-2 layer.

18. The elastic member of claim 1, wherein the first layer includes a 1-1 layer and a 1-2 layer on the 1-1 layer,
wherein a yield strength of the 1-2 layers is greater than that of the 1-1 layers.

19. The elastic member of claim 1, wherein the first layer includes a 1-1 layer, a 1-2 layer on the 1-1 layer, and a 1-3 layer on the 1-2 layer,
wherein a thermal conductivity of the 1-1 layer and a thermal conductivity of the 1-3 layer are greater than the thermal conductivity of the 1-2 layer.

20. The elastic member of claim 1, wherein the first layer includes a 1-1 layer, a 1-2 layer on the 1-1 layer, and a 1-3 layer on the 1-2 layer,
wherein a yield strength of the 1-2 layer is greater than a yield strength of the 1-1 layer and the yield strength of the 1-3 layer.

21. The elastic member of claim 1, wherein the second layer includes plastic, and
the second layer has a thickness of 15% to 25% of the overall thickness of the elastic member.

22. The elastic member of claim 1, wherein the second layer includes a metal, and
the second layer has a thickness of 4% to 10% of the overall thickness of the elastic member.

23. The elastic member of claim 1, wherein a tangent delta of the third layer is 0.2 to 1.8 at room temperature (25° C.)

24. The elastic member of claim 1, wherein a thickness of the elastic member is 150 μm to 300 μm.

25. The elastic member of claim 1, wherein the third layer is disposed while filling the inside of the pattern portion.

26. The elastic member of claim 25, wherein the third layer is disposed while partially filling the inside of the pattern portion.

27. A folding support comprising:
an elastic member of claim 1; and
a protective layer disposed under the elastic member.

28. A display device comprising:
an elastic member of claim 1;
a protective layer under the elastic member;
an adhesive layer on the elastic member; and
a panel layer on the adhesive layer,
wherein the panel layer includes at least one of a display panel and a touch panel.
